(19) United States
(12) Patent Application Publication
(10) Pub. No.: US 2009/0183047 A1
(43) Pub. Date: Jul. 16, 2009

(54) Method for Generating Ldpc Codes and Apparatus Using Ldpc Codes

(76) Inventors: Mattias Lampe, Beijing (CN); Youyun Xu, Shanghai (CN); Halbin Zhang, Shanghai (CN); Yu Pan, Shanghai (CN); Hulfeng Shi, Shanghai (CN)

Correspondence Address: STAAS & HALSEY LLP, SUITE 700, 1201 NEW YORK AVENUE, N.W., WASHINGTON, DC, 20005, US

(21) Appl. No.: 12/224,841

(22) PCT Filed: Nov. 29, 2006
(86) PCT No.: PCT/EP2006/069054

§ 371 Date: Dec. 1, 2008

(30) Foreign Application Priority Data
Mar. 6, 2006 (CN) 200610056707 X
Jul. 7, 2006 (GB) 0613437.3

(51) Int. Cl. H03M 13/05; G06F 11/10

(52) U.S. Cl. 714/752; 714/E11.032

(57) ABSTRACT

A method for generating an LDPC (low density parity check) code, comprising steps of: determining the number of rows and the number of columns in a matrix for forming the LDPC code according to predetermined code rate and constraint length; dividing the matrix into a plurality of layers according to a predetermined column weight; selecting a parallelization factor; dividing at least one of said layers in the matrix into a plurality of sub-layers and dividing each said sub-layer into a plurality of modular data blocks, according to the parallelization factor; determining the position of each weighted element in each modular data block according to said column weight and a predetermined row weight, so as to form said LDPC code.

This invention relates to the technical field of error-correcting codes, and particularly to a method for generating linear error-correcting codes of LDPC (low density parity check) codes and an apparatus utilizing this method.

LDPC (Low Density Parity Check) codes are linear error-correcting codes with a sparse check matrix. Since they have the advantages of approaching the “Shannon limit”, low system complexity and easy realization, LDPC codes have shown good prospects for application in the field of digital communication, particularly in the wireless communication field using orthogonal frequency-division multiplexing.

By using a check matrix formed by a LDPC code, not only can the encoded information received from a receiving terminal be decoded, but also a generating matrix can be obtained by certain conversions, such as Gauss elimination, which generating matrix can be used to encode information from a transmitting terminal. Therefore, in current research efforts regarding LDPC codes most of the proposed technical solutions concern LDPC code encoders or LDPC code decoders.

Among the proposed LDPC code encoders, for example, there is an encoder using quasi-cyclic LDPC codes; because of the use of a digital feedback shift register for encoding, this LDPC code encoder has a reduced complexity. However, when the check matrix obtained from its LDPC code is used in decoding, it cannot achieve the expected throughput. Here, the throughput is relevant to the code rate, the iteration number set in the decoder, the clock frequency used and the parallelization selected for the decoder circuit.

Among the proposed LDPC code decoders, for example, there is an LDPC code decoder adopting a parallel structure; due to the elimination of the conflicts generated when the same memory is accessed to store the data calculated simultaneously, the throughput of this LDPC code decoder has achieved an effective increase. However, when the generating matrix obtained from this LDPC code is used in encoding, it leads to an extremely complicated design of encoder.

Therefore, the construction of a suitable LDPC code, which can make full use of the strong error-correcting advantage of the LDPC code, and also take care of performance in the two aspects of encoding complexity and decoding throughput, is becoming a center of focus in the current research efforts regarding LDPC codes.

An object of this invention is to provide a method for generating LDPC codes, which method can make a flexible design of an LDPC code according to an expected throughput, so as to significantly increase a decoder's decoding rate without increasing the complexity of the LDPC code encoder.

Another object of this invention is to provide a method for use in an LDPC code decoder, which method can make full use of the parallelization in a decoding circuit, so as to ensure a fast decoding rate and also to save the consumption of hardware resources in the decoder.

Yet another object of this invention is to provide a method for use in an LDPC code encoder, which method further reduces the complexity of an LDPC code encoder under the prerequisite of an ensured achievement of an expected throughput.

In accordance with a first aspect of the present invention, a method for generating an LDPC (low density parity check) code comprises steps of: determining the number of rows and the number of columns in a matrix for forming the LDPC code according to a predetermined code rate and constraint length; dividing the matrix into a plurality of layers according to a predetermined column weight; selecting a parallelization factor; dividing at least one of said layers in the matrix into a plurality of sub-layers and dividing each said sub-layer into a plurality of modular data blocks, according to the parallelization factor; determining the position of each weighted element in each modular data block according to said column weight and a predetermined row weight, so as to form said LDPC code.

In accordance with a second aspect of the present invention, an encoding method using an encoding code formed by a matrix obtained from an LDPC code, is characterised in that, the method for generating said LDPC code comprises steps of: determining the number of rows and the number of columns in a matrix for forming the LDPC code according to a predetermined code rate and constraint length; dividing the matrix into a plurality of layers according to a predetermined column weight; selecting a parallelization factor; dividing at least one of said layers in the matrix into a plurality of sub-layers and dividing each said sub-layer into a plurality of modular data blocks, according to the parallelization factor; determining the position of each weighted element in each modular data block according to said column weight and a predetermined row weight, so as to form the matrix for forming said LDPC code; said encoding method further comprises steps of: creating a diagonal matrix in the upper right corner of the matrix forming said LDPC code by performing a matrix calculation; and encoding the data to be transmitted by using the LDPC code having said diagonal matrix.

In accordance with a third aspect of the present invention, a decoding method using a decoding code formed by a matrix obtained from an LDPC code, is characterised in that the method for generating said LDPC code comprises steps of: determining the number of rows and the number of columns in a matrix for forming the LDPC code according to a predetermined code rate and constraint length; dividing the matrix into a plurality of layers according to a predetermined column weight; selecting a parallelization factor; dividing at least one of said layers in the matrix into a plurality of sub-layers and dividing each said sub-layer into a plurality of modular data blocks, according to the parallelization factor; determining the position of each weighted element in each modular data block according to said column weight and a predetermined row weight, so as to form the matrix for forming said LDPC code; said decoding method further comprises steps of: obtaining a check matrix by using the matrix forming said LDPC code; and decoding received data by using said check matrix.

In accordance with a fourth aspect of the present invention, an encoder using an encoding code formed by a matrix obtained from an LDPC code, is characterised in that a module for forming said encoding code comprises a module for generating said LDPC code: said LDPC code generating module determines the number of rows and the number of columns in the matrix for forming the LDPC code according to a predetermined code rate and constraint length; divides the matrix into a plurality of layers according to a predetermined column weight; divides at least one of said layers in the matrix into a plurality of sub-layers and divides each said sub-layer into a plurality of modular data blocks according to a selected parallelization factor; and determines the position of each weighted element in each modular data block according to said column weight and a predetermined row weight, so as to form the matrix for forming said LDPC code; said module for forming the encoding code performs a matrix calculation to the LDPC code formed by the module for generating said LDPC code, so as to create a diagonal matrix in the upper right corner of the matrix forming said LDPC code; and encodes the data to be transmitted by using the LDPC code having said diagonal matrix.

In accordance with a fifth aspect of the present invention, a decoder using a decoding code formed by a check matrix obtained from an LDPC code, is characterised in that a module for forming said decoding code comprises a module for generating said LDPC code: said LDPC code generating module determines the number of rows and the number of columns in the matrix for forming the LDPC code according to a predetermined code rate and constraint length; divides the matrix into a plurality of layers according to a predetermined column weight; divides at least one of said layers in the matrix into a plurality of sub-layers and divides each said sub-layer into a plurality of modular data blocks according to a selected parallelization factor; and determines the position of each weighted element in each modular data block according to said column weight and a predetermined row weight, so as to form the matrix for forming said LDPC code; said module for forming the decoding code obtains a check matrix by using said matrix forming said LDPC code; and decodes received data by using said check matrix.

By reference to the description hereinbelow in conjunction with the drawings and the contents of the claims, and with more comprehensive understanding of this invention, other objects and effects of this invention will become clearer and more readily understandable.

This invention is described hereinbelow in detail by way of embodiments with reference to the drawings, in which:

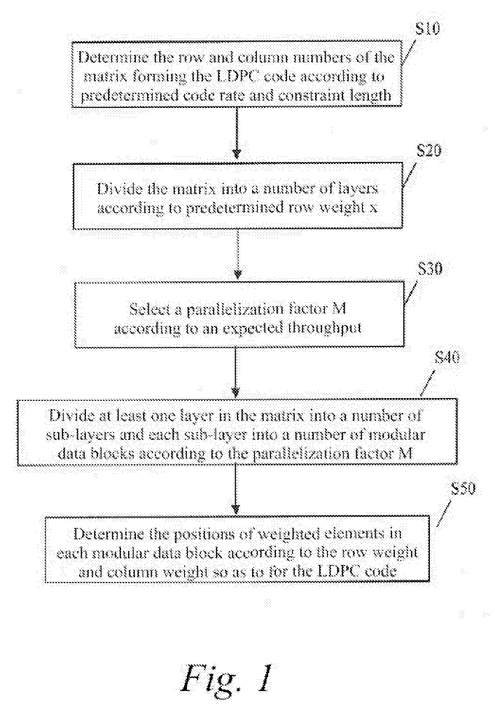

FIG. 1 is a flow chart of an embodiment of the method for generating an LDPC code according to this invention;

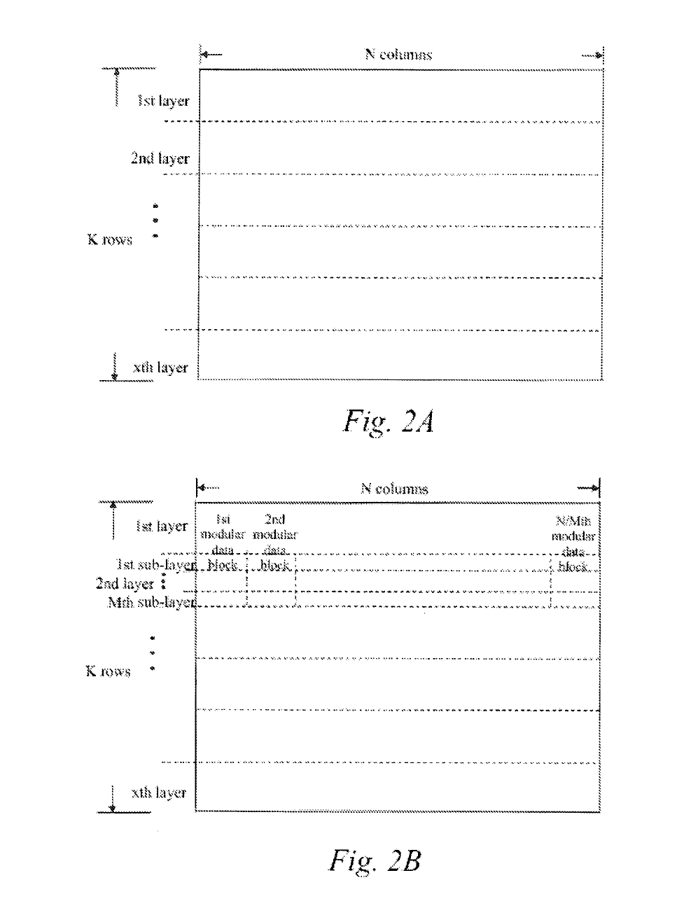

FIG. 2A is a diagram illustrating the layers in a matrix forming the LDPC code, according to an embodiment of the method for generating the LDPC code of this invention;

FIG. 2B is an illustrative diagram showing the layers being further divided into sub-layers and modular data blocks, according to an embodiment of the method for generating LDPC code of this invention;

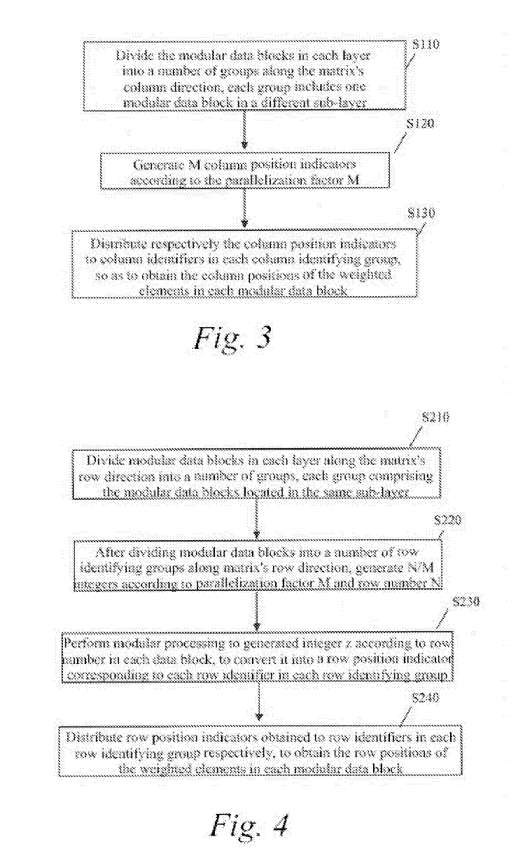

FIG. 3 is a flow chart for determining the column position of nonzero elements in each modular data block, according to an embodiment of the method for generating LDPC code of this invention;

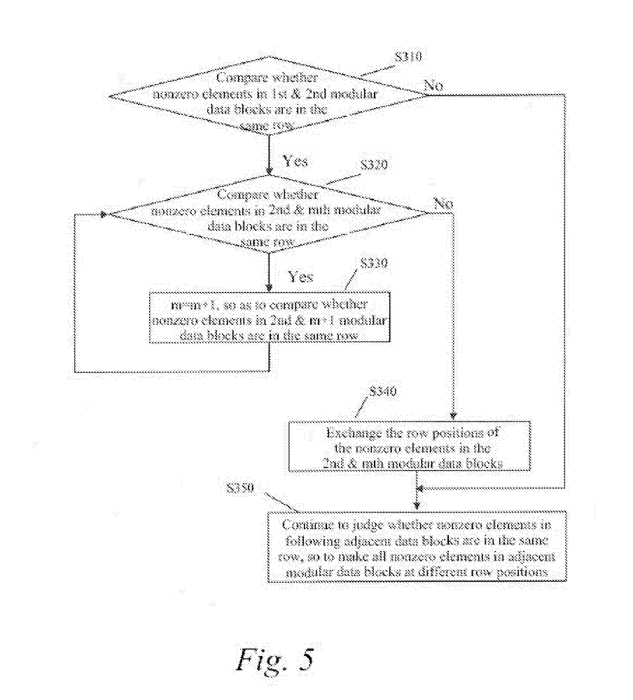

FIG. 4 is a flow chart for determining the row position of nonzero elements in each modular data block, according to an embodiment of the method for generating LDPC code of this invention;

FIG. 5 is a flow chart for adjusting the row position of nonzero elements in modular data blocks, according to an embodiment of the method for generating LDPC code of this invention; and

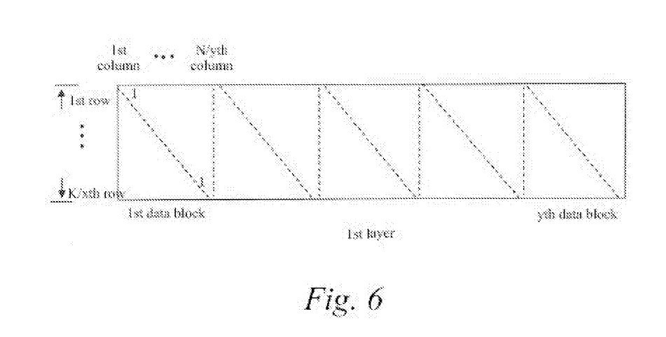

FIG. 6 is an illustrative diagram showing the first layer division of the matrix of LDPC code, according to an embodiment of the method for generating LDPC code of this invention.

In all the drawings, identical reference numerals represent the same or similar features or functions.

In the method for generating an LDPC code of this invention, when constructing a matrix of the LDPC code, firstly, the matrix is divided into a number of sub-layers, and each sub-layer is divided into a number of modular data blocks according to the parallelization which may be adopted in a decoder circuit, then the position of nonzero elements, namely the weighted elements, in each modular data block is determined according to a predetermined column weight and row weight. Since in this manner of constructing an LDPC code full consideration has been given to the parallel processing structure in a decoder circuit, the decoding throughput can therefore be effectively increased.

Hereinbelow, on the basis of one embodiment of this invention, the above method of the invention for generating an LDPC code is described in detail with reference to the drawings:

FIG. 1 is a flow chart of an embodiment of the method for generating an LDPC code according to this invention. As shown in FIG. 1, firstly, according to a predetermined code rate and constraint length, the number of rows and the number of columns in a matrix for forming the LDPC code are determined (step S10). For an LDPC code, the code rate R is usually represented by the following equation (1):

R=1−K/N=1−x/y equation (1)

wherein, N represents the number of columns in the matrix, and its value is decided by the predetermined constraint length for the LDPC code; K represents the number of rows in the matrix, and its value is decided by the predetermined code rate and constraint length; x represents the column weight of the matrix, namely the number of nonzero elements “1” contained in each column of the matrix; and y represents the row weight of the matrix, namely the number of nonzero elements “1” contained in each row of the matrix.

Following the above, according to the column weight x, the matrix is divided into a number of layers (step S20). In consideration of the code rate, in the step S20, it is better to use the only column weight in each column of each layer, namely the matrix is divided into x layers, and each column of each layer has only one nonzero element. A matrix divided into x layers can be seen in FIG. 2A.

Thereafter, according to an expected throughput, a parallelization factor is selected (step S30). Since the throughput is relevant to the code rate, the iteration number set in the decoder and the clock frequency used, when selecting the parallelization factor the parallelization factor M should be made to satisfy the following equation (2):

M≧(T·L)/(R·F) equation (2)

wherein, T represents the expected throughput, L represents the iteration number set in the decoder, R is the code rate, and F is the clock frequency used in the encoder.

According to the selected parallelization factor M, at least one layer in the above x layers is divided into a number of sub-layers, and each sub-layer is further divided into a number of modular data blocks (step S40). Here, the number of sub-layers includes two or more than two sub-layers. Particularly, when Mod(K, x·M)=0, each layer is divided into M sub-layers along the row direction of the matrix; and each sub-layer is further divided into N/M modular data blocks along the column direction of the matrix.

After the above division, in each sub-layer there are K/x/M rows and N columns of elements, i.e. the size of each sub-layer is (K/x/M)·N; while in each modular data block, there are K/x/M rows and M columns of elements, i.e. the size of each modular data block is (K/x/M)·M.

FIG. 2B is an illustrative diagram showing a second layer being divided into M sub-layers and each sub-layer being divided into N/M modular data blocks. Then, according to the predetermined column weight x and row weight y, the positions of nonzero elements, namely the weighted element, in each modular data block are determined, so as to form the LDPC code (step S50). In consideration of the code rate, the row weight and column weight should be made as evenly distributed in each modular data block as possible. In the preferred embodiment of this invention, there exists in each modular data block only one weighted element, i.e. in each modular data block there is only one nonzero element.

Hereinbelow, the determination of the nonzero elements' column positions and row positions in each modular data block in this invention is described with reference to FIGS. 3 and 4.

FIG. 3 is a flow chart of determining the column positions of nonzero elements in each modular data block, according to an embodiment of the method for generating LDPC code in this invention. As shown in FIG. 3, firstly, the modular data blocks in a layer which has been divided into a number of sub-layers (for example, the M sub-layers in the second layer of the above-mentioned embodiment) are divided into a number of groups along the matrix's column direction, and each group comprises respectively one modular data block in a different sub-layer (step S110).

For example, assuming the second layer is divided into M sub-layers and N/M modular data blocks, along the matrix's column direction:

the first modular data block in the first sub-layer, the first modular data block in the second sub-layer, . . . the first modular data block in the Mth sub-layer together form a first group;

the second modular data block in the first sub-layer, the second modular data block in the second sub-layer, . . . the second modular data block in the Mth sub-layer together form a second group; . . . .

the N/Mth modular data block in the first sub-layer, the N/Mth modular data block in the second sub-layer, . . . the N/Mth modular data block in the Mth sub-layer together form the N/Mth group.

As to these groups formed by division along the matrix's column direction, each group therein is called, in this invention, a column identifying group. Each column identifying group comprises a number of column identifiers for identifying the modular data blocks located in different sub-layers.

The column identifying groups formed by the above division can be represented by a two-dimensional number group a[i][j], wherein i is for identifying a modular data block, with a value range of iε[1 . . . N/M] in this embodiment, and j is for identifying a sub-layer, with a value range of jε[1 . . . M] in this embodiment.

Therefore, a[1][j], a[2][j], a[3][j] . . . a[N/M][j] represent respectively different column identifying groups; and the column identifiers in each column identifying group, namely the group with the same i value but different j values represents the modular data blocks located in different sub-layers.

According to the above definition, in this embodiment, the first modular data blocks located in different sub-layers form the column identifying group a[1][j], the second modular data blocks located in different sub-layers form the column identifying group a[2][j] . . . and the N/Mth modular data blocks located in different sub-layers form the column identifying group a[N/M][j], i.e. there are a total of N/M column identifying groups. Since the value range for j is jε[1 . . . M], each column identifying group comprises M column identifiers.

Therefore, for example, the column identifying group a[2][j] consists of a total of M column identifiers of a[2][1], a[2][2], a[2][3] . . . a[2][M], wherein each column identifier represents a second modular data block located respectively in the first sub-layer, second sub-layer, third sub-layer . . . Mth sub-layer.

After having divided the modular data blocks into a number of column identifying groups along said matrix's column direction in the above-mentioned manner, M column position indicators are generated according to the parallelization factor M (step S120). Each column position indicator corresponds to the column position of a nonzero element in a modular data block.

Since there are a total of 1, 2 . . . M columns in one modular data block, accordingly, M column position indicators are generated in step S120, numbered 1, 2 . . . M respectively, for identifying the column positions of the nonzero elements in each modular data block.

Then these column position indicators are distributed respectively to the column identifiers in each column identifying group, so as to obtain the column positions of the nonzero elements in each modular data block (step S130). These column position indicators 1, 2, . . . M, are distributed respectively to the column identifiers in the column identifying groups a[1][j], a[2][j] . . . a[N/M][j], so as to obtain the column positions of the nonzero elements in each modular data block.

Since different column position indicators correspond to different column positions in the modular data blocks, and each column identifier in each column identifying group identifies respectively a modular data block located in a different sub-layer, therefore, in step S130, when the different column indicators are distributed to different column identifiers, the modular data blocks located in different sub-layers in the same column identifying group would be distributed with different column positions; therefore, in step S130, no matter whether the distribution is done randomly or by a specific method, it would always satisfy the predetermined column weight and the specific scheme described above with this embodiment that “there is only one column weight in each column of each layer” and “there exists only one weighted element in each modular data block”.

After having determined the column positions of the nonzero elements in each modular data block, it will be described hereinbelow with reference to FIG. 4, the process of determining the row positions of the nonzero elements in each modular data block according to the method for generating an LDPC code in an embodiment of this invention.

As shown in FIG. 4, firstly, the modular data blocks in each layer are divided into a number of groups along the matrix's row direction, and each group comprises modular data blocks located in the same sub-layer (step S210).

The second layer can be taken as an example. Assuming the modular data blocks located in the first sub-layer form the first group, the modular data blocks located in the second sub-layer form the second group . . . the modular data blocks located in the Mth sub-layer form the Mth group, then in step S210, it will get M groups.

As to these groups formed by division along the matrix's row direction, each one of them, in this invention, can be called a row identifying group. Each row identifying group comprises a number of row identifiers for identifying the modular data blocks in the same sub-layer.

These row identifying groups formed by the above division can be represented by a two-dimensional number group b[i][j], wherein i is used to identify a sub-layer with a value range of iε[1 . . . M] in this embodiment, and j is used to identify a modular data block, with a value range of jε[1 . . . N/M] in this embodiment.

Therefore, b[1][j], b[2][j], . . . b[M][j] represent respectively different row identifying groups; and the row identifiers in each row identifying group, i.e. the number group with the same i value but different j values, represents the modular data blocks located in the same sub-layer.

According to the above definition and in this embodiment, the modular data blocks no. 1, 2 . . . N/M of a total of N/M located in the first sub-layer form the row identifying group b[1][j], the modular data blocks no. 1, 2 . . . N/M of a total of N/M located in the second sub-layer form the row identifying group b[2][j], . . . , the modular data blocks no. 1, 2 . . . N/M of a total of N/M located in the Mth sub-layer form the row identifying group b[M][j], i.e. there are a total of M row identifying groups. Since j has a value range of jε[1 . . . N/M], therefore, each row identifying group comprises N/M row identifiers.

Therefore, for example, the row identifying group b[2][j] represents a total of N/M row identifiers formed by b[2][1], b[2][2], . . . b[2][N/M], wherein each row identifier represents the first modular data block, the second modular data block . . . the N/Mth modular data block located in the second sub-layer.

According to the above method, after having divided these modular data blocks into a number of row identifying groups along said matrix's row direction, N/M integers are generated (step S230) according to the parallelization factor M and the row number N, if z is used to represent the integer generated, the value of z should be, respectively, 1, 2 . . . N/M.

Thereafter, modular calculation is applied to the generated integer z according to the row number in each modular data block (in this embodiment, the row number in each modular data block is K/x/M), so as to convert it into a row position indicator corresponding to each row identifier in a row identifying group (step S230). Each row position indicator corresponds to the row position of a nonzero element in the modular data block.

For example, the row position indicator corresponding to a row identifier in the row identifying group b[n][j] in the nth sub-layer can be calculated by the following equation (3):

b[n][j]=Mod(z,K/x/M)+1 equation (3)

It can be seen that since the largest value of the integer z is N/M, according to the equation (3), it can obtain (N/M)/(K/x/M) groups of row position indicators, with the values in each group being 1, 2 . . . K/x/M.

Then, the row position indicators obtained by equation (3) are distributed respectively to each row identifier in each row identifying group, so as to obtain the row position of the nonzero elements in each modular data block (step S240). That is, the row position indicators of the above (N/M)/(K/x/M) groups, with the values in each group being 1, 2 . . . K/x/M, are distributed respectively to the row identifiers of the row identifying groups b[1][j], b[2][j] . . . b[M][j], so as to obtain the row positions of the nonzero elements in each modular data block.

Since each row identifier in each row identifying group identifies respectively the different modular data blocks located in the same sub-layer, therefore, in step S240, when the different row position indicators are distributed to different row identifiers, it would satisfy the specific scheme described above with this embodiment that “there exists only one weighted element in each modular data block”; furthermore, it is known from the above equation (1) that K/N=x/y, the (N/M)/(K/x/M) groups of row position indicators generated above becomes y groups of row position indicators, therefore, in step S240, no matter whether the distribution is done randomly or by a specific method, it would conform to the predetermined row weight.

The process for determining the column positions and row positions of the nonzero elements in each modular data block, as described above with reference to FIGS. 3 and 4, is only one preferred embodiment. When constructing an LDPC matrix, other matrices can also be constructed according to the predetermined row weight and column weight; for example, it is not necessary to limit to only one column weight in each column in each layer, and it is also not necessary to limit to only one weighted element in each modular data block.

Furthermore, according to the specific scheme in this preferred embodiment that “there is only one column weight in each column of each layer” and “there exists only one weighted element in each modular data block”, it can also adopt a method different from that described with reference to FIGS. 3 and 4, for determining the column positions and row positions of the nonzero elements in each modular data block.

In order to further describe the above method for generating LDPC code according to this invention, hereinbelow, an LDPC matrix constructed according to the above preferred embodiment of this invention is described in conjunction with specific parameters. When selecting these parameters, if the matrix's column number N, the parallelization factor M and the row weight y satisfy the following equation (4), then there can be a relatively good construction result:

N<M·y·6 equation (4)

The specific parameters that have been set include: the parallelization factor M=2, the matrix's column number N=72, the row number K=36, the column weight x=3, the row weight y=6, the code rate R=0.5.

Firstly, according to the column weight x=3, the matrix is divided into three layers, and according to the above preferred embodiment it is set that in each column of each layer there is only one nonzero element; then, according to the parallelization factor M=2, the second layer in the matrix, for example, is divided into 2 sub-layers along the matrix's row direction; further according to the parallelization factor M=2, each sub-layer in the second layer is divided along the matrix's column direction into 36 modular data blocks (36=N/M=72/2).

Therefore in the second layer there are two sub-layers, and each sub-layer's size is 6 rows by 72 columns; each sub-layer comprises 36 modular data blocks and the size of each data block is 6 rows by 2 columns.

Next the column positions and row positions of the nonzero elements in each modular data block in the second layer are determined.

(1) Determine the Column Positions of the Nonzero Elements in each Modular Data Block

Firstly, according to the parallelization factor M=2, the modular data blocks in the second layer are divided along the matrix's column direction into 36 column identifying groups, with each column identifying group containing 2 column identifiers. Namely, according to the above preferred embodiment, for the column identifying group a[i][j], i has a value range of 1 to 36, and j has a value range of 1 to 2; and the column identifiers a[1][1] and a[1][2] form a column identifying group, the column identifiers a[2][1] and a[2][2] form a column identifying group . . . the column identifiers a[36][1] and a[36][2] form a column identifying group, so there is a total of 36 column identifying groups.

Then, according to the parallelization factor M=2, 2 column position indicators are generated, and the values for these two column position indicators are 1 and 2 respectively, corresponding to the first column and the second column in each modular data block respectively.

These two column position indicators are randomly distributed to the 2 row identifiers in each column identifying group, so as to obtain the column position of the nonzero element in each modular data block.

(2) Determine the Row Positions of the Nonzero Elements in each Modular Data Block

Firstly, according to the parallelization factor M=2, the modular data blocks in the second layer are divided along the matrix's row direction into 2 column identifying groups, with each column identifying group containing 36 row identifiers. Namely, according to the above preferred embodiment, for the row identifying group b[i][j], i has a value range of 1 to 2, and j has a value range of 1 to 36; and the column identifiers b[1][1], b[1][2] . . . b[1][36] form a row identifying group and the row identifiers b[2][1], b[2][2] . . . b[2][36] form a row identifying group, so a total of 2 row identifying groups.

Following the above, according to the parallelization factor M=2 and column number N=72, 36 integers are generated, (36=N/M), and using z to represent these 36 integers, then the value of z is, respectively 1, 2 . . . 36.

Then, according to the row number 6 in each modular data block, the above equation (3) is used to apply modular calculation to the generated integers z, so as to convert them into the row position indicators corresponding to the row identifiers in each row identifying group.

As to the first sub-layer, from b[n][1]=Mod(z, 6)+1, it can obtain 6 groups, each group having a value of 1 to 6 for a total of 36 row position indicators, wherein the values 1 to 6 in each group correspond respectively to the row 1 to row 6 in each modular data block.

The obtained 36 row position indicators are distributed randomly to the row indicators in each row identifying group, so as to obtain the row position of the nonzero elements in each modular data block.

As described in the above preferred embodiment, the matrix constructed in this method would not only meet the predetermined row weight of 6 and column weight of 3, but also satisfy the design scheme of the preferred embodiment of “there is only one column weight in each column of each layer” and “there exists only one weighted element in each modular data block”.

After having determined the column positions and row positions of the nonzero elements in each modular data block, and in order to make it easy to realize the hardware of the decoder circuit, to increase the clock speed during decoding, and to save hardware resources used by decoding, further adjustments can be made to the row positions of the nonzero elements in the modular data block so that the nonzero elements in the adjacent modular data blocks along the matrix's row direction are located at different row positions.

Hereinbelow, an embodiment of this invention of the process for adjusting the row positions of the nonzero elements in a modular data block is described with reference to FIG. 5.

As shown in FIG. 5, the number n sub-layer is used as an example. Firstly, the nonzero element in the first modular data block in this sub-layer is compared with the nonzero element in the second modular data block to see whether they are in the same row (step S310).

If the nonzero elements in the first and second modular data blocks are in the same row, the row position of the nonzero element in another modular data block (assuming it is the modular data block no. m) in the same sub-layer but not adjacent to the second modular data block is examined (step S320).

If the row position of the nonzero element in the modular data block no. m is different from the row position of the nonzero element in the second modular data block, the row position of the nonzero element in the second modular data block is exchanged with the row position of the nonzero element in the modular data block no. m (step S330).

That is, assuming that initially the nonzero elements in the first and second modular data blocks are both at the first row position, and the nonzero element in the modular data block no. m is at the third row position, then after the exchange of the row positions, the nonzero element in the second modular data block is at the third row position, and the nonzero element in the modular data block no. m is at the first row position.

If the nonzero element in the modular data block no. m is also in the same row as the nonzero element in the second modular data block, then further examination is made of another modular data block (step S340), for example the row position of the nonzero element in the modular data block no. m+1, to judge whether the row position of the nonzero element in this modular data block is different from the row position of the nonzero element in the second modular data block, so as to make an exchange with the row position of the nonzero element in the second modular data block.

After it has been determined that the row positions of the nonzero elements in the first and second modular data blocks are different, further judgments are made regarding the second and third modular data blocks, and any following adjacent modular data block pairs in the same sub-layer to see whether their nonzero elements are in the same row, so that after the above mentioned adjustment process, the nonzero elements in any adjacent modular data blocks in the same sub-layer are all at different row positions (step S350).

In the preferred embodiment of this invention, in order to further reduce the complexity of LDPC code encoder and during the process of constructing the above mentioned LDPC matrix, the first layer of the matrix can be constructed according to the following method.

Specifically, firstly, the first layer is divided along the matrix's column direction into a number of corresponding data blocks according to the predetermined row weight. In the embodiment of this invention, the row weight is y, therefore it is divided into y data blocks.

As to the matrix of K rows and N columns in this embodiment, according to the column weight x, the size of each data block is K/x rows by N/y columns.

According to the specific scheme of “there is only one column weight in each column of each layer”, in each data block, namely in the sub-matrix of K/x rows and N/y columns, nonzero elements are set along the diagonal line of this sub-matrix, so as to construct the illustrative diagram shown in FIG. 6, in which the first layer of an LDPC matrix has y sub-matrices, and each sub-matrix has nonzero elements “1” arranged along a diagonal line.

After having constructed an LDPC code of this invention by the above method, a check matrix can be obtained from this LDPC code, which check matrix is to be used in a decoder for decoding; as to the matrix formed by this LDPC code, it is processed by using RU algorithm or iteration algorithm, so as to obtain the code for use in the LDPC code encoder. Wherein, this RU algorithm is recorded in detail in an article of a title “Efficient Encoding of Low-Density Parity-Check Codes”, by T. Richardson and R. Urbanke, in IEEE Transactions on Information Theory, P657-670, Vol. 47, 2001.

In the preferred embodiment of this invention, when designing an LDPC code encoder, an LDPC code obtained by the above method is used as a basis, and conventional calculation is made to the matrix forming said LDPC code, for example, it can adopt the calculation methods such as position exchange between rows in the matrix, or position exchange between columns, or performing modular 2 addition to the rows, etc. so as to create a diagonal matrix in the upper right corner of this LDPC matrix, and to use the obtained LDPC code having this diagonal matrix as the code for the LDPC encoder, thus to further simplify the design of an LDPC code encoder. The more rows and columns this diagonal matrix comprises, the lower is the complexity for realizing the LDPC code encoder.

At the side of the transmitting end, the LDPC code with said diagonal matrix is used for encoding the data to be transmitted, and then the encoded data are sent out.

While at the side of the receiving end, a check matrix formed by said LDPC code is used in the decoder during the decoding process to decode the received data encoded by the code, so as to obtain the data sent by the transmitting end.

According to the method for generating LDPC code in this invention, because when the LDPC matrix is constructed, a decision is made, according to the parallelization factor that can be adopted in the encoder circuit, to further divide the matrix into sub-layers and each sub-layer into modular data blocks, and then the LDPC matrix is formed by determining the positions of nonzero elements in each modular data block according to the predetermined row weight and column weight. Therefore, by using this LDPC matrix, not only can it design flexibly the check matrix for decoding, but it can also achieve a fast decoding speed at the time of decoding to reach an expected throughput; in addition, by this manner of dividing the LDPC matrix into modular data blocks, it will not increase the complexity of the encoder when this LDPC code is used for encoding.

Furthermore, according to the method for generating an LDPC code in this invention, when determining the positions of the nonzero elements in each modular data block, the nonzero elements in the adjacent modular data blocks in each sub-layer are adjusted to different row positions; in this way it can also increase the decoder's clock speed and save the consumption of hardware resources in the decoder when it is used for decoding.

In addition, according to the method for generating an LDPC code in this invention, by forming a diagonal matrix in the upper right corner of the LDPC matrix, it can further reduce the complexity of the LDPC code encoder.

Since LDPC codes have shown excellent error-correcting functions (code gain), therefore the encoding and decoding based on the LDPC codes generated by this invention are not restricted merely to the field of wireless communication, they also have good application perspectives in wire communication networks, digital broadcasting and television systems, media storage systems, including hard-disc signal processing circuits, and many other technical fields.

Those skilled in the art should understand that all kinds of improvements can be made to the method for generating LDPC code disclosed above in this invention without departing from the basic contents of this invention. Therefore, the scope of protection for this invention should be determined by the contents of the claims attached herewith.

1-30. (canceled)

31. A method for generating a low density parity check code, comprising:
determining a number of rows and a number of columns in a matrix for forming the low density parity check code according to a predetermined code rate and constraint length;
dividing the matrix into layers according to a predetermined column weight;
selecting a parallelization factor;
dividing at least one of the layers in the matrix into sub-layers and dividing each sub-layer into modular data blocks, according to the parallelization factor; and
determining a position of each of weighted elements in each modular data block according to the predetermined column weight and a predetermined row weight, so as to form the low density parity check code.

32. The method as claimed in claim 31, wherein said dividing the matrix includes dividing the matrix into corresponding layers according to column weight, so that when there is only one column weight existing in each column of every layer, the column weight of each column in the matrix conforms to the predetermined column weight.

33. The method as claimed in claim 32, wherein said selecting of the parallelization factor is according to at least one of the following factors: the predetermined code rate, a predetermined iteration number used for decoding and/or a clock frequency, and an expected throughput.

34. The method as claimed in claim 33, wherein said dividing the at least one of the layers in the matrix comprises:
dividing the layers into corresponding sub-layers according to the parallelization factor; and
dividing each sub-layer into corresponding modular data blocks according to the parallelization factor and a column number of the matrix, so that when there is only one weighted element present in each modular data block, a row weight of each row in the sub-layer conforms to the predetermined row weight.

35. The method as claimed in claim 34, wherein said determining the position of each weighted element comprises:
dividing the modular data blocks into column identifying groups along a column direction of the matrix, with each column identifying group having column identifiers identifying the modular data blocks located in different sub-layers;
generating corresponding column position indicators according to the parallelization factor, with the column position indicators identifying a column position of the weighted elements in the modular data blocks; and
distributing respectively the column position indicators to the column identifiers in each column identifying group, so as to obtain column positions of the weighted elements in each of the modular data blocks.

36. The method as claimed in claim 35, wherein said determining the position of each weighted element comprises:
dividing the modular data blocks into row identifying groups along a row direction of the matrix, with each row identifying group having row identifiers identifying the modular data blocks located in same sub-layers;
generating corresponding numbers convertible to row position indicators according to the parallelization factor and the column number;
performing modular calculation on the corresponding numbers according to a row number in the modular data blocks, so as to obtain the row position indicators, which indicate a row position of the weighted elements in the modular data blocks; and
distributing respectively the row position indicators to the row identifiers in each row identifying group, so as to obtain row positions of the weighted elements in each of the modular data blocks.

37. The method as claimed in claim 36, wherein said determining the position of each weighted element further comprises adjusting the row position of the weighted element in each modular data block, so as to locate at least the weighted elements in adjacent modular data blocks at different row positions.

38. The method as claimed in claim 37, further comprising:
dividing the first of the layers into corresponding data blocks according to the row weight; and
setting the elements located on a diagonal line in each of the data blocks as the weighted elements.

39. An encoding method using an encoding code formed by a matrix obtained from a low density parity check code, comprising:
determining a number of rows and a number of columns in a matrix for forming the low density parity check code according to a predetermined code rate and constraint length;
dividing the matrix into layers according to a predetermined column weight;
selecting a parallelization factor;
dividing at least one of the layers in the matrix into sub-layers and dividing each the sub-layer into modular data blocks, according to the parallelization factor;
determining a position of each of weighted elements in each modular data block according to the predetermined column weight and a predetermined row weight, so as to form the matrix for forming the low density parity check code;
creating a diagonal matrix in the upper right corner of the matrix forming the low density parity check code by performing a matrix calculation; and
encoding data to be transmitted by using the low density parity check code having the diagonal matrix.

40. The method as claimed in claim 39, wherein said dividing the matrix includes dividing into corresponding layers according to column weight, so that when there is only one column weight existing in each column of every layer, the column weight of each column in the matrix conforms to the predetermined column weight.

41. The method as claimed in claim 40, wherein said dividing the at least one of the layers in the matrix comprises:
dividing the layers into corresponding sub-layers according to the parallelization factor; and
dividing each sub-layer into corresponding modular data blocks according to the parallelization factor and a column number of the matrix, so that when there is only one weighted element existing in each modular data block, a row weight of each row in the sub-layer conforms to the predetermined row weight.

42. The method as claimed in claim 41, wherein said determining the position of each weighted element comprises:
dividing the modular data blocks into column identifying groups along a column direction of the matrix, with each column identifying group having column identifiers identifying the modular data blocks located in different sub-layers;
generating corresponding column position indicators, according to the parallelization factor, identifying a column position of the weighted elements in the modular data blocks; and
distributing respectively the column position indicators to the column identifiers in each column identifying group, so as to obtain column positions of the weighted elements in each of the modular data blocks.

43. The method as claimed in claim 42, wherein said determining the position of each weighted element further comprises:
dividing the modular data blocks into row identifying groups along a row direction of the matrix, with each row identifying group having row identifiers identifying the modular data blocks located in same sub-layers;
generating corresponding numbers convertible to row position indicators according to the parallelization factor and the column number;
performing modular calculation on the corresponding numbers according to a row number in the modular data blocks, so as to obtain the row position indicators, which indicate a row position of the weighted elements in the modular data blocks; and
distributing respectively the row position indicators to the row identifiers in each row identifying group, so as to obtain row positions of the weighted elements in each of the modular data blocks.

44. A decoding method using a decoding code formed by a matrix obtained from a low density parity check code, comprising:
determining a number of rows and a number of columns in a matrix for forming the low density parity check code according to a predetermined code rate and constraint length;
dividing the matrix into layers according to a predetermined column weight;
selecting a parallelization factor;
dividing at least one of the layers in the matrix into sub-layers and dividing each sub-layer into modular data blocks, according to the parallelization factor;
determining a position of each of weighted elements in each modular data block according to the predetermined column weight and a predetermined row weight, so as to form the matrix for forming the low density parity check code;
obtaining a check matrix by using the matrix forming the low density parity check code; and
decoding received data using the check matrix.

45. The method as claimed in claim 44, wherein said dividing the matrix includes:
dividing the matrix into corresponding layers according to column weight, so that when there is only one column weight existing in each column of every layer, the column weight of each column in the matrix conforms to the predetermined column weight.

46. The method as claimed in claim 45, wherein said dividing the at least one of the layers in the matrix comprises:
dividing the layers into corresponding sub-layers according to the parallelization factor; and
dividing each sub-layer into corresponding modular data blocks according to the parallelization factor and a column number of the matrix, so that when there is only one weighted element existing in each modular data block, a row weight of each row in the sub-layer conforms to the predetermined row weight.

47. The method as claimed in claim 46, wherein said determining the position of each weighted element comprises:
dividing the modular data blocks into column identifying groups along a column direction of the matrix, with each column identifying group having column identifiers identifying the modular data blocks located in different sub-layers;
generating corresponding column position indicators according to the parallelization factor, with the column position indicators identifying a column position of the weighted elements in the modular data blocks;
distributing respectively the column position indicators to the column identifiers in each column identifying group, so as to obtain column positions of the weighted elements in each of the modular data blocks.

48. The method as claimed in claim 47, wherein said determining the position of each weighted element further comprises:
dividing the modular data blocks into row identifying groups along a row direction of the matrix, with each row identifying group having row identifiers identifying the modular data blocks located in same sub-layers;
generating corresponding numbers convertible to row position indicators according to the parallelization factor and the column number;
performing modular calculation on the corresponding numbers according to a row number in the modular data blocks, so as to obtain the row position indicators, which indicate a row position of the weighted elements in the modular data blocks;
distributing respectively the row position indicators to the row identifiers in each row identifying group, so as to obtain row positions of the weighted elements in each of the modular data blocks.

49. The method as claimed in claim 48, wherein said determining the position of each weighted element further comprises adjusting the row position of the weighted element in each the modular data block, so as to locate at least the weighted elements in adjacent modular data blocks at different row positions.

50. An encoder using an encoding code formed by an encoding matrix obtained from a low density parity check code, comprising:
a module forming the encoding code, including
a module generating the low density parity check code by determining a number of rows and a number of columns in an initial matrix for forming the low density parity check code according to a predetermined code rate and constraint length, dividing the initial matrix into layers according to a predetermined column weight; dividing at least one of the layers in the initial matrix into sub-layers; dividing each sub-layer into modular data blocks according to a selected parallelization factor; and determining a position of each of weighted elements in each modular data block according to the predetermined column weight and a predetermined row weight, so as to form a formation matrix for forming the low density parity check code, and
a module performing a matrix calculation on the low density parity check code, so as to create a diagonal matrix in the upper right corner of the formation matrix and encoding data to be transmitted by using the low density parity check code having the diagonal matrix.

51. The encoder as claimed in claim 50, wherein said module generating the low density parity check code divides the initial matrix into corresponding layers according to column weight, so that when there is only one column weight existing in each column of every layer, the column weight of each column in the initial matrix conforms to the predetermined column weight.

52. The encoder as claimed in claim 51, wherein said module generating the low density parity check code:
divides the layers into corresponding sub-layers according to the parallelization factor; and
divides each sub-layer into corresponding modular data blocks according to the parallelization factor and a column number of the matrix, so that when there is only one weighted element existing in each modular data block, a row weight of each row in the sub-layer conforms to the predetermined row weight.

53. The encoder as claimed in claim 52, wherein said module generating the low density parity check code:
divides the modular data blocks into column identifying groups along a column direction of the initial matrix, with each column identifying group having column identifiers identifying the modular data blocks located in different sub-layers;
generates corresponding column position indicators according to the parallelization factor, with the column position indicators identifying a column position of the weighted elements in the modular data blocks;
distributes respectively the column position indicators to the column identifiers in each column identifying group, so as to obtain column positions of the weighted elements in each of the modular data blocks.

54. The encoder as claimed in claim 53, wherein said module generating the low density parity check code:
divides the modular data blocks into row identifying groups along a row direction of the initial matrix, with each row identifying group having row identifiers identifying the modular data blocks located in same sub-layers;
generates corresponding numbers convertible to row position indicators according to the parallelization factor and the column number;
performs modular calculation on the corresponding numbers according to a row number in the modular data blocks, so as to obtain the row position indicators, which indicate a row position of the weighted elements in the modular data blocks;
distributes respectively the row position indicators to the row identifiers in each row identifying group, so as to obtain row positions of the weighted elements in each of the modular data blocks.

55. A decoder using a decoding code formed by a check matrix obtained from a low density parity check code, comprising:
a module forming the decoding code including
a module generating the low density parity check code by determining a number of rows and a number of columns in an initial matrix for forming the low density parity check code according to a predetermined code rate and constraint length; dividing the initial matrix into layers according to a predetermined column weight; dividing at least one of the layers in the initial matrix into sub-layers, dividing each the sub-layer into modular data blocks according to a selected parallelization factor; and determining a position of each weighted element in each modular data block according to the predetermined column weight and a predetermined row weight, so as to form a formation matrix for forming the low density parity check code; and
a module forming the decoding code by obtaining a check matrix using the formation matrix and decoding received data by using the check matrix.

56. The decoder as claimed in claim 55, wherein said module generating the low density parity check code divides the initial matrix into corresponding layers according to column weight, so that when there is only one column weight existing in each column of every layer, the column weight of each column in the matrix conforms to the predetermined column weight.

57. The decoder as claimed in claim 56, wherein said module generating the low density parity check code:
divides the layers into corresponding sub-layers according to the parallelization factor; and
divides each sub-layer into corresponding modular data blocks according to the parallelization factor and the column number of the matrix, so that when there is only one weighted element existing in each modular data block, the row weight of each row in the sub-layer conforms to the predetermined row weight.

58. The decoder as claimed in claim 57, wherein said module generating the low density parity check code:
divides the modular data blocks into column identifying groups along the column direction of the initial matrix, with each column identifying group having column identifiers identifying the modular data blocks located in different sub-layers;
generates corresponding column position indicators according to the parallelization factor, with the column position indicators identifying a column position of the weighted elements in the modular data blocks;
distributes respectively the column position indicators to the column identifiers in each column identifying group, so as to obtain column positions of the weighted elements in each of the modular data blocks.

59. The decoder as claimed in claim 58, wherein said module generating the low density parity check code:
divides the modular data blocks into row identifying groups along a row direction of the initial matrix, with the row identifying group having row identifiers identifying the modular data blocks located in same sub-layers;
generates corresponding numbers convertible to row position indicators according to the parallelization factor and the column number;
performs modular calculation on the corresponding numbers according to the row number in the modular data blocks, so as to obtain the row position indicators which indicate a row position of the weighted elements in the modular data blocks;
distributes respectively the row position indicators to the row identifiers in each row identifying group, so as to obtain row positions of the weighted elements in each of the modular data blocks.

60. The decoder as claimed in claim 59, wherein said module generating the low density parity check code adjusts the row position of the weighted element in each the modular data block, so as to locate at least the weighted elements in adjacent modular data blocks at different row positions.
